(19) United States
(12) Patent Application Publication
(10) Pub. No.: US 2026/0221195 A1
(43) Pub. Date: Jul. 30, 2026

(54) MULTI-WORDLINE PROGRAMMING WITH DATA LOSS PREVENTION

(71) Applicant: Micron Technology, Inc., Boise, ID (US)

(72) Inventors: Luis Iam, San Jose, CA (US); Devin Batutis, San Jose, CA (US); Jianmin Huang, San Carlos, CA (US)

(21) Appl. No.: 19/036,901

(22) Filed: Jan. 24, 2025

(51) Int. Cl. G11C 16/10

(52) U.S. Cl. CPC G11C 16/105

(57) ABSTRACT

Various example embodiments provide for multi-wordline programming of a memory device with data loss prevention, which can be used by a memory sub-system. In particular, various example embodiments use a certain sequence of memory device commands to avoid multi-wordline data loss during cache programming of a memory device.

### TECHNICAL FIELD

Example embodiments of the disclosure relate generally to memory devices and, more specifically, to block failure protection for multi-wordline programming of a memory device with data loss prevention, which can be used by a memory sub-system.

### BACKGROUND

A memory sub-system can include one or more memory devices that store data. The memory devices can be, for example, non-volatile memory devices and volatile memory devices. In general, a host system can utilize a memory sub-system to store data at the memory devices and to retrieve data from the memory devices.

### BRIEF DESCRIPTION OF THE DRAWINGS

The disclosure will be understood more fully from the detailed description given below and from the accompanying drawings of various example embodiments of the disclosure. The drawings, however, should not be taken to limit the disclosure to the specific example embodiments, but are for explanation and understanding only.

FIG. 1 is a block diagram illustrating an example computing system that includes a memory sub-system, in accordance with some example embodiments of the present disclosure.

FIG. 2 and FIG. 3 are flow diagrams of example methods for multi-wordline programming of a memory device with data loss prevention, in accordance with some example embodiments of the present disclosure.

FIG. 4 is a block diagram of an example computer system in which example embodiments of the present disclosure may operate.

### DETAILED DESCRIPTION

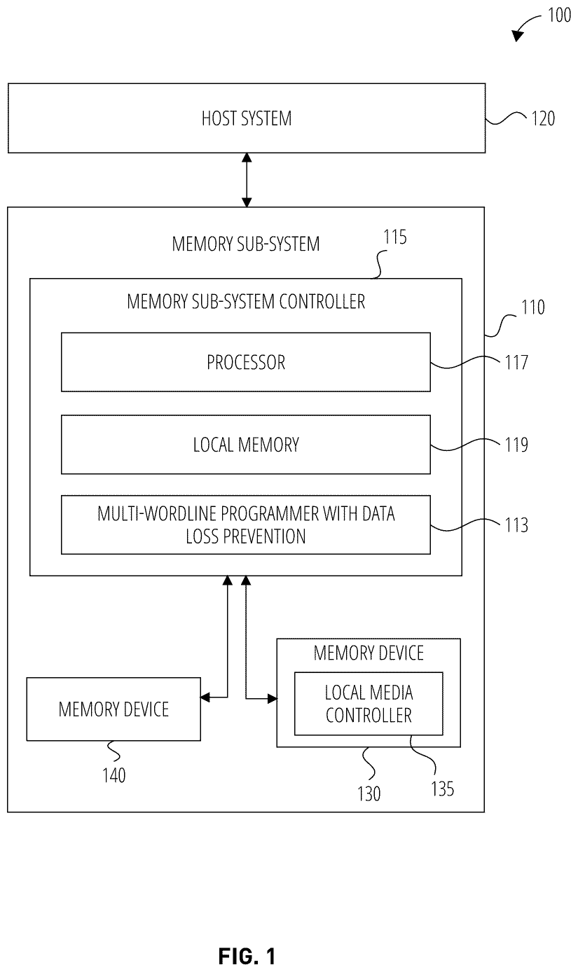

Aspects of the present disclosure are directed to using a memory device command sequence to avoid multi-wordline data loss during memory device programming, which can be used by a memory sub-system. A memory sub-system can be a storage device, a memory module, or a hybrid of a storage device and memory module. Examples of storage devices and memory modules are described below in conjunction with FIG. 1. In general, a host system can utilize a memory sub-system that includes one or more components, such as memory devices that store data. The host system can send access requests to the memory sub-system, such as to store data at the memory sub-system and to read data from the memory sub-system.

The host system can send access requests (e.g., write commands, read commands) to the memory sub-system, such as to store data on a memory device at the memory sub-system, read data from the memory device on the memory sub-system, or write/read constructs with respect to a memory device on the memory sub-system. The data to be read or written, as specified by a host request (e.g., data access request or command request), is hereinafter referred to as “host data.” A host request can include logical address information (e.g., logical block address (LBA), namespace) for the host data, which is the location the host system associates with the host data. The logical address information (e.g., LBA, namespace) can be part of metadata for the host data. Metadata can also include error handling data (e.g., error-correcting code (ECC) codeword, parity code), data version (e.g., used to distinguish age of data written), valid bitmap (which LBAs or logical transfer units contain valid data), and so forth.

As used herein, a logical memory address can comprise a logical block address (LBA), which can be provided by a host system to a memory device or a memory sub-system. For example, depending on a physical interface used between a host system and a memory device/memory sub-system, an LBA can comprise a 2-byte or 4-byte number. As used herein, a physical memory address can comprise a memory address on a memory device or a memory sub-system where data (e.g., user data) is stored. For example, the physical memory address can comprise a physical block address (PBA), which can be a position within an underling non-volatile memory device that can be identified by a 4-byte number or a tuple of numbers (e.g. die ID, block ID, page ID). As used herein, an address mapping data can comprise logical memory address-to-physical memory address (L2P) data (e.g., L2P mapping or translation table), which can associate (and therefore facilitate translation or reconstruction of) a logical memory address to a physical memory address of a memory device or a memory sub-system.

The memory sub-system can initiate media management operations, such as a write operation, on host data that is stored on a memory device. For example, firmware of the memory sub-system may re-write previously written host data from a location of a memory device to a new location as part of garbage collection management operations. The data that is re-written, for example as initiated by the firmware, is hereinafter referred to as “garbage collection data.”

“User data” hereinafter generally refers to host data and garbage collection data. “System data” hereinafter refers to data that is created and/or maintained by the memory sub-system for performing operations in response to host requests and for media management. Examples of system data include, and are not limited to, system tables (e.g., logical-to-physical memory address mapping table (also referred to herein as a L2P table), data from logging, scratch pad data, and so forth).

A memory device can be a non-volatile memory device. A non-volatile memory device is a package of one or more die. Each die can be comprised of one or more planes. For some types of non-volatile memory devices (e.g., NAND-type devices), each plane is comprised of a set of physical blocks. For some memory devices, blocks are the smallest area that can be erased. Each block is comprised of a set of pages. Each page is comprised of a set of memory cells, which store bits of data. The memory devices can be raw memory devices (e.g., NAND), which are managed externally, for example, by an external controller. The memory devices can be managed memory devices (e.g., managed NAND), which are a raw memory device combined with a local embedded controller for memory management within the same memory device package. The memory device can be divided into one or more zones where each zone is associated with a different set of host data or user data or application.

Certain memory devices, such as NAND-type memory devices, comprise one or more blocks, (e.g., multiple blocks) with each of those blocks comprising multiple pages, where each page comprises a subset of memory cells of the block, and where a single wordline of a block (which connects a group of memory cells of the block together) defines one or more pages of a block (depending on the type of memory cell). A threshold voltage (VT) of a memory cell (of a block) can be the voltage at which the floating gate (e.g., NAND transistor), implementing the memory cell, turns on and conducts (e.g., to a bit line coupled to the memory cell). Generally, writing data to NAND-type memory devices involves programming (by way of a program operation) the NAND-type memory devices at the page level of a block, and erasing data from such memory devices involves erasing the memory devices at the block level (e.g., page level erasure of data is not possible).

Depending on the embodiment, different blocks can comprise different types of memory cells. For instance, a block (a single-level cell (SLC) block) can comprise multiple SLCs, a block (a multi-level cell (MLC) block) can comprise multiple MLCs, a block (a triple-level cell (TLC) block) can comprise multiple TLCs, and a block (a quad-level cell (QLC) block) can comprise QLCs. Other blocks comprising other types of memory cells (e.g., higher-level memory cells, having higher bit storage-per-cell) are also possible. Each worldline (of a block) can define one or more pages depending on the type of memory cells (of the block) connected to the wordline. For example, for an SLC block, a single wordline can define a single page. For an MLC block, a single wordline can define two pages—a lower page (LP) and an upper page (UP). For a TLC block, a single wordline can define three pages—a lower page (LP), an upper page (UP), and an extra page (XP). For a QLC block, a single wordline can define four pages—a lower page (LP), an upper page (UP), an extra page (XP), and a top page (TP) page. As used herein, a page of LP page type can be referred to as a “LP page,” a page of UP page type can be referred to as a “UP page,” a page of XP page type can be referred to as a “XP page,” and a page of TP page type can be referred to as a “TP page.” Each page type can represent a different level of a cell (e.g., QLC can have a first level for LPs, a second level for UPs, a third level for XPs, and a fourth level for TPs). To write data to a given page, a wordline associated with the given page is programmed according to a page programming algorithm (e.g., that causes one or more voltage pulses or pulses to memory cells of a block based on the memory). Generally, programming a single wordline of a block results all the pages in the single wordline being programmed, where the number pages being programmed depends on the type of block. For example, programming a single wordline of a QLC block usually results in four pages (e.g., LP, UP, XP, TP pages) associated with the single wordline being programmed.

Memory sub-systems can employ error-correction techniques, such as using a redundant array of independent NAND-type flash memory devices (hereafter, referred to as a RAIN technique), to protect data (e.g., host or user data) stored on the memory sub-systems. Error-correction techniques can comprise calculating parity (e.g., exclusive OR (XOR) parity) across some collection of data (e.g., host/user data) being error-protected. By such error-correction techniques, if a data member of the collection is lost (e.g., corrupted) for any reason, the parity calculation can be re-performed and the lost data recreated.

Conventional NAND-type memory devices commonly employ cache programming techniques to enhance performance. In cache programming, data transfer operations for a next wordline (WLn+1) occur simultaneously while programming a current wordline (WLn). This allows the conventional NAND-type memory device to store WLn+1 data in the NAND latch during WLn programming operations, enabling the device to immediately begin programming WLn+1 once WLn programming completes.

Generally, in architectures of NAND-type memory devices, memory cells are organized into multiple planes, with each plane having its own data latch. The programming sequence typically involves transferring data across multiple page types (e.g., lower page (LP), upper page (UP), and extra page (XP) for a TLC block)—for each plane. Additionally, the data transfer process generally uses both external and internal registers within the NAND-type memory device, where the external register interfaces with a controller (e.g., a memory sub-system controller of a memory sub-system), while internal registers store the data that will be programmed into memory cells of the NAND-type memory device. Usually, when data is transferred from the controller (e.g., memory sub-system controller) to the NAND-type memory device, it is first stored in the external register before being copied to the internal registers.

Conventional cache programming implementations for a NAND-type memory device permit the controller (e.g., memory sub-system controller) to release its buffer (e.g., erase stored data in the buffer) once data has been transferred to one or more of the NAND-type memory device's latches. This approach optimizes system resources by freeing up controller memory (e.g., local memory of the memory sub-system controller) as soon as the data transfer is complete, without waiting for confirmation that the programming operation has successfully finished.

While memory sub-systems implementing memory protection schemes such as RAIN can help maintain data integrity in cases where programming operations encounter issues, conventional architecture typically provide protection capabilities for a limited number of wordline failures within a block. Specifically, where a conventional NAND-type memory device implements cache programming, a failure during programming of a current wordline (WLn) can corrupt data in both the current and previous wordline (WLn−1). Since cache programming transfers the next wordline's data (WLn+1) to the NAND device before confirming successful programming of WLn, such failures can result in data loss across three wordlines, exceeding typical RAIN protection schemes that only protect against two wordline failures.

Various example embodiments described herein cure these and other deficiencies of conventional memory technology by providing multi-wordline programming of a memory device with data loss prevention, which can be used by a memory sub-system. In particular, various example embodiments use a certain sequence of memory device commands to avoid multi-wordline data loss during cache programming of a memory device. According to various example embodiments, when programming a current wordline (WLn) on a set of memory die planes of a memory device (e.g., of a memory sub-system), the sequence of memory device commands used to transfer data to the memory device (e.g., to a set of latches of the memory device) for a next wordline (WLn+1) on the set of memory die planes causes the memory device to delay final programming of the next wordline (WLn+1) after the transfer of the data is complete. For various example embodiments, programming of the next wordline (WLn+1) does not occur (e.g., start) until after the memory device confirms that the current wordline (WLn) has been successfully programmed. This is unlike conventional cache programming, where the sequence of memory device commands used causes the next wordline (WLn+1) to start programming as soon as the transfer of the data to the memory device (e.g., to the set of latches) is complete. For various example embodiments, if the memory device indicates that the current wordline (WLn) has been successfully programmed, the programming of the next wordline (WLn+1) is started using the data already transferred to the memory device (e.g., data stored in the set of latches of the memory device). If, however, the memory device indicates that the current wordline (WLn) has not been successfully programmed, various example embodiments prevent the programming of the next wordline (WLn+1) to start, thereby avoiding (e.g., safeguarding against) unnecessary loss of the data for the next wordline (WLn+1), which was transferred to the memory device (e.g., to the set of latches of the memory device) and awaiting programming to the next wordline (WLn+1).

For alternative example embodiments, when programming a current wordline (WLn) on a set of memory die planes of a memory device of a memory sub-system, a sequence of memory device commands causes data to be transferred from a buffer of the memory sub-system (e.g., buffer space allocated on a local memory of the memory sub-system controller) to the memory device (e.g., to a set of latches of the memory device) for a next wordline (WLn+1) on the set of memory die planes and causes the memory device to start final programming of the next wordline (WLn+1) after the transfer of the data is complete. According to various embodiments, after the transfer of the data is complete, the data (for the next wordline (WLn+1)) stored in the buffer of the memory sub-system is retained and released (e.g., erased or allowed to be erased) from the buffer only after the memory device confirms (to the memory sub-system controller) that the current wordline (WLn) has been successfully programmed. This is unlike conventional cache programming, where data in the buffer of the memory sub-system is released after the transfer from the buffer to the memory device (e.g., to the set of latches) is complete. If the memory device indicates that the current wordline (WLn) has not been successfully programmed, various example embodiments prevent the data (for the next wordline (WLn+1)) from being released from the buffer, thereby avoiding (e.g., safeguarding against) unnecessary loss of the data for the next wordline (WLn+1), which the memory device already removed from the set of latches during the memory device's attempt to program the data to the next wordline (WLn+1).

Overall, various example embodiments described herein provide a solution to the technical problem that occurs when a programming failure of the current wordline (WLn) during cache programming of a memory device (e.g., NAND-type memory device) corrupts data in both the current and previous wordlines (WLn and WLn−1), which results in data loss across three wordlines (typical RAIN protection schemes only protect against two wordline failures). Use of various example embodiments described herein maintains the performance benefits of hiding data transfer latency during cache programming operations while preventing data loss across three (or more) wordlines. Additionally, various example embodiments described herein can be implemented in existing memory sub-systems without firmware architecture changes or increased controller buffer sizes (e.g., on the memory sub-system controller).

As used herein, a physical memory location of a memory die can comprise a block, a page, or a memory cell. For instance, where a physical memory location comprises a page or a memory cell, a set of physical memory locations can represent a single block or multiple blocks. The set of physical memory locations can be a set of contiguous physical memory locations. As used herein, storing data on one or more physical memory locations of a memory die can comprise writing data to the one or more physical memory locations, where the writing can comprise programming one or more pages of a block with the data.

Disclosed herein are some examples of multi-wordline programming of a memory device with data loss prevention, as described herein.

FIG. 1 illustrates an example computing system 100 that includes a memory sub-system 110, in accordance with some example embodiments of the present disclosure. The memory sub-system 110 can include media, such as one or more volatile memory devices (e.g., memory device 140), one or more non-volatile memory devices (e.g., memory device 130), or a combination of such.

A memory sub-system 110 can be a storage device, a memory module, or a hybrid of a storage device and memory module. Examples of a storage device include a solid-state drive (SSD), a flash drive, a universal serial bus (USB) flash drive, a secure digital (SD) card, an embedded Multi-Media Controller (eMMC) drive, a Universal Flash Storage (UFS) drive, and a hard disk drive (HDD). Examples of memory modules include a dual in-line memory module (DIMM), a small outline DIMM (SO-DIMM), and various types of non-volatile dual in-line memory module (NVDIMM).

The computing system 100 can be a computing device such as a desktop computer, laptop computer, network server, mobile device, a vehicle (e.g., airplane, drone, train, automobile, or other conveyance), Internet of Things (IoT) enabled device, embedded computer (e.g., one included in a vehicle, industrial equipment, or a networked commercial device), or such computing device that includes memory and a processing device.

The computing system 100 can include a host system 120 that is coupled to one or more memory sub-systems 110. In some example embodiments, the host system 120 is coupled to different types of memory sub-systems 110. FIG. 1 illustrates one example of a host system 120 coupled to one memory sub-system 110. As used herein, “coupled to” or “coupled with” generally refers to a connection between components, which can be an indirect communicative connection or direct communicative connection (e.g., without intervening components), whether wired or wireless, including connections such as electrical, optical, magnetic, and the like.

The host system 120 can include a processor chipset and a software stack executed by the processor chipset. The processor chipset can include one or more cores, one or more caches, a memory controller (e.g., NVDIMM controller), and a storage protocol controller (e.g., a peripheral component interconnect express (PCIe) controller, serial advanced technology attachment (SATA) controller). The host system 120 uses the memory sub-system 110, for example, to write data to the memory sub-system 110 and read data from the memory sub-system 110.

The host system 120 can include or be coupled to the memory sub-system 110 so that the host system 120 can read data from or write data to the memory sub-system 110. The host system 120 can be coupled to the memory sub-system 110 via a physical host interface. Examples of a physical host interface include, but are not limited to, a serial advanced technology attachment (SATA) interface, a peripheral component interconnect express (PCIe) interface, a compute express link (CXL) interface, a universal serial bus (USB) interface, a Fibre Channel interface, a Serial Attached SCSI (SAS) interface, etc. The physical host interface can be used to transmit data between the host system 120 and the memory sub-system 110. The host system 120 can further use an NVM Express (NVMe) interface to access the memory devices 130, 140 when the memory sub-system 110 is coupled with the host system 120 by the PCIe or CXL interface. The physical host interface can provide an interface for passing control, address, data, and other signals between the memory sub-system 110 and the host system 120.

The memory devices 130, 140 can include any combination of the different types of non-volatile memory devices and/or volatile memory devices. The volatile memory devices (e.g., memory device 140) can be, but are not limited to, random access memory (RAM), such as dynamic random access memory (DRAM) and synchronous dynamic random access memory (SDRAM).

Some examples of non-volatile memory devices (e.g., memory device 130) include a NAND type flash memory and write-in-place memory, such as a three-dimensional (3D) cross-point memory device, which is a cross-point array of non-volatile memory cells. A cross-point array of non-volatile memory can perform bit storage based on a change of bulk resistance, in conjunction with a stackable cross-gridded data access array. Additionally, in contrast to many flash-based memories, cross-point non-volatile memory can perform a write in-place operation, where a non-volatile memory cell can be programmed without the non-volatile memory cell being previously erased. NAND type flash memory includes, for example, two-dimensional (2D) NAND and 3D NAND.

Each of the memory devices 130, 140 can include one or more arrays of memory cells. One type of memory cell, for example, SLCs, can store one bit per cell. Other types of memory cells, such as MLCs, TLCs, and QLCs, can store multiple bits per cell. In some example embodiments, each of the memory devices 130, 140 can include one or more arrays of memory cells such as SLCs, MLCs, TLCs, QLCs, or any combination of such. In some example embodiments, a particular memory device can include an SLC portion, and an MLC portion, a TLC portion, or a QLC portion of memory cells. The memory cells of the memory devices 130, 140 can be grouped as pages that can refer to a logical unit of the memory device used to store data. With some types of memory (e.g., NAND), pages can be grouped to form blocks. As used herein, a block comprising SLCs can be referred to as a SLC block, a block comprising MLCs can be referred to as an MLC block, a block comprising TLCs can be referred to as a TLC block, and a block comprising QLCs can be referred to as a QLC block.

Although non-volatile memory components such as NAND type flash memory (e.g., 2D NAND, 3D NAND) and 3D cross-point array of non-volatile memory cells are described, the memory device 130 can be based on any other type of non-volatile memory, such as read-only memory (ROM), phase change memory (PCM), self-selecting memory, other chalcogenide-based memories, ferroelectric transistor random-access memory (FeTRAM), ferroelectric random access memory (FeRAM), magneto random access memory (MRAM), Spin Transfer Torque (STT)-MRAM, conductive bridging RAM (CBRAM), resistive random access memory (RRAM), oxide-based RRAM (OxRAM), negative-or (NOR) flash memory, and electrically erasable programmable read-only memory (EEPROM).

A memory sub-system controller 115 (or controller 115 for simplicity) can communicate with the memory devices 130, 140 to perform operations such as reading data, writing data, or erasing data at the memory devices 130, 140 and other such operations. The memory sub-system controller 115 can include hardware such as one or more integrated circuits and/or discrete components, a buffer memory, or a combination thereof. The hardware can include digital circuitry with dedicated (i.e., hard-coded) logic to perform the operations described herein. The memory sub-system controller 115 can be a microcontroller, special purpose logic circuitry (e.g., a field programmable gate array (FPGA), an application specific integrated circuit (ASIC), etc.), or other suitable processor.

The memory sub-system controller 115 can include a processor (processing device) 117 configured to execute instructions stored in local memory 119. In the illustrated example, the local memory 119 of the memory sub-system controller 115 includes an embedded memory configured to store instructions for performing various processes, operations, logic flows, and routines that control operation of the memory sub-system 110, including handling communications between the memory sub-system 110 and the host system 120.

In some example embodiments, the local memory 119 can include memory registers storing memory pointers, fetched data, and so forth. The local memory 119 can also include ROM for storing micro-code. While the example memory sub-system 110 in FIG. 1 has been illustrated as including the memory sub-system controller 115, in another example embodiment of the present disclosure, a memory sub-system 110 does not include a memory sub-system controller 115, and can instead rely upon external control (e.g., provided by an external host, or by a processor or controller separate from the memory sub-system).

In general, the memory sub-system controller 115 can receive commands or operations from the host system 120 and can convert the commands or operations into instructions or appropriate commands to achieve the desired access to the memory device 130 and/or the memory device 140. The memory sub-system controller 115 can be responsible for other operations such as wear leveling operations, garbage collection operations, error detection and ECC operations, encryption operations, caching operations, and address translations between a logical address (e.g., LBA, namespace) and a physical memory address (e.g., physical block address) that are associated with the memory devices 130, 140. The memory sub-system controller 115 can further include host interface circuitry to communicate with the host system 120 via the physical host interface. The host interface circuitry can convert the commands received from the host system 120 into command instructions to access the memory device 130 and/or the memory device 140 as well as convert responses associated with the memory device 130 and/or the memory device 140 into information for the host system 120.

The memory sub-system 110 can also include additional circuitry or components that are not illustrated. In some example embodiments, the memory sub-system 110 can include a cache or buffer (e.g., DRAM) and address circuitry (e.g., a row decoder and a column decoder) that can receive an address from the memory sub-system controller 115 and decode the address to access the memory devices 130, 140.

In some example embodiments, the memory device 130 includes local media controller 135 that operates in conjunction with memory sub-system controller 115 to execute operations on one or more memory cells of the memory device 130. An external controller (e.g., memory sub-system controller 115) can externally manage the memory device 130 (e.g., perform media management operations on the memory device 130). In some example embodiments, a memory device 130 is a managed memory device, which is a raw memory device combined with a local controller (e.g., local media controller 135) for media management within the same memory device package. An example of a managed memory device is a managed NAND (MNAND) device.

The memory sub-system controller 115 includes a multi-wordline programmer with data loss prevention 113 (hereafter, the multi-wordline programmer 113) that enables or facilitates the memory sub-system controller 115 to multi-wordline programming of a memory device (e.g., 130, 140) with data loss prevention in accordance with various example embodiments described herein. Alternatively, some or all of the multi-wordline programmer 113 is included by the local media controller 135, thereby enabling the local media controller 135 to enable or facilitate multi-wordline programming with data loss prevention.

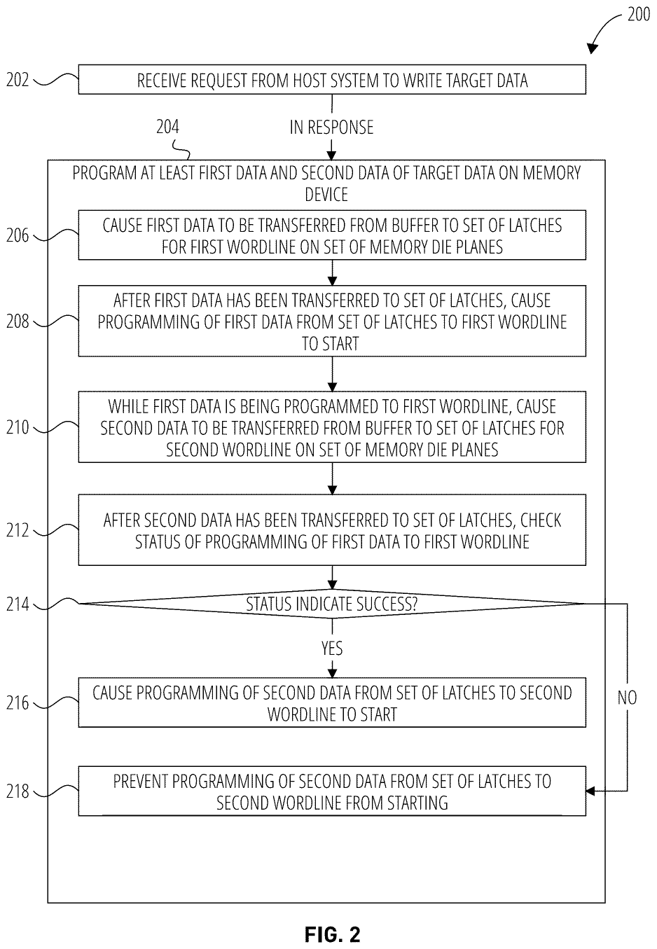

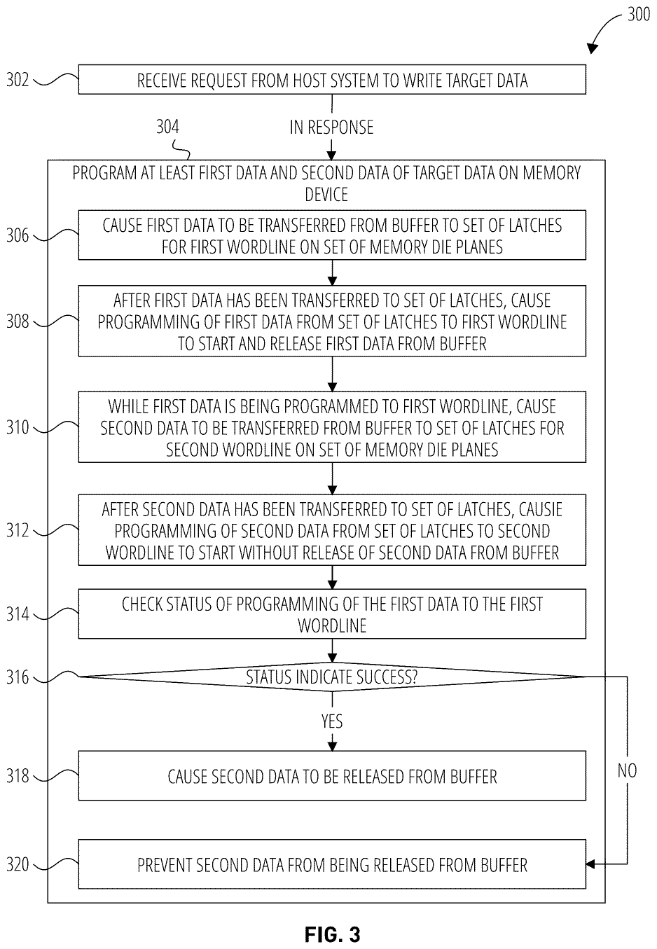

FIG. 2 and FIG. 3 are flow diagrams of example methods 200, 300 for multi-wordline programming of a memory device with data loss prevention, in accordance with some example embodiments of the present disclosure. Each of methods 200, 300 can represent an alternative approach to performing cache programming on a memory device in accordance with some example embodiments. Any of methods 200, 300 can be performed by processing logic that can include hardware (e.g., processing device, circuitry, dedicated logic, programmable logic, microcode, hardware of a device, integrated circuit, etc.), software (e.g., instructions run or executed on a processing device), or a combination thereof. In some example embodiments, any of methods 200, 300 is performed by the memory sub-system controller 115 of FIG. 1 based on the multi-wordline programmer 113. Additionally, or alternatively, for some example embodiments, any of methods 200, 300 is performed, at least in part, by the local media controller 135 of the memory device 130 of FIG. 1. Although shown in a particular sequence or order, unless otherwise specified, the order of the processes can be modified. Thus, the illustrated example embodiments should be understood only as examples, and the illustrated processes can be performed in a different order, and some processes can be performed in parallel. Additionally, one or more processes can be omitted in various example embodiments. Thus, not all processes are used in every example embodiment. Other process flows are possible.

Referring now to FIG. 2, at operation 202 a processing device (e.g., the processor 117 of the memory sub-system controller 115) receives a request from a host system (e.g., 120) to write target data (e.g., write target data on the memory device 130). According to various example embodiments, the request received from the host system comprises a request to write user data for storage on a memory sub-system. For various example embodiments, the memory sub-system comprises a memory device (e.g., 130, 140) comprising a set of memory die planes and a set of latches for the set of memory die planes, where each memory die plane comprises a plurality of consecutive wordlines of memory cells. For instance, the memory device can comprise one or more memory die, where each memory die can comprise multiple memory die planes, and each memory die plane has its own dedicated latch.

In response to the request received at operation 202, at operation 204 the processing device causes at least first data and second data of the target data to be programmed on the memory device. As shown, during operation 204, the processing device performs operations 206 through 218.

At operation 206, the processing device causes the first data to be transferred, from a buffer associated with the processing device (e.g., buffer space allocated on the local memory 119 of the memory sub-system controller 115 that includes the processor 117) to a set of latches of the memory device, for a first wordline (of the plurality of consecutive wordlines of the memory device) on the set of memory die planes. For various example embodiments, each memory die plane of the memory device has a dedicated latch such that each latch is configured to store data for programming pages a wordline on a different memory die plane of the set of memory die planes. Operation 206 can comprise sending a set of commands from the processing device (e.g., processor 117) to the memory device (e.g., 130, 140). Additionally, for some example embodiments, the processing device causes data to be transferred to the set of latches for one page type at a time. For instance, the processing device can cause the transfer of the first data such that: first portions of the first data are transferred to the set of latches for each page of a first page type defined by the first wordline on each memory die plane of the set of memory die planes; and then second portions of the first data are transferred to the set of latches for each page of a second page type defined by the first wordline on each memory die plane of the set of memory die planes. Depending on the example embodiment, this can continue for each additional page types being written to. Examples of page types can include, without limitation: lower page (LP) and upper page (UP) types for where memory cells of the memory device are (or are being used as) MLCs; lower page (LP) and upper page (UP), extra page (XP) types for where memory cells of the memory device are (or are being used as) TLCs; and lower page (LP) and upper page (UP), extra page (XP), and top page (TP) types for where memory cells of the memory device are (or are being used as) QLCs.

According to some example embodiments, the transfer of the first data comprises transferring the first data from a buffer of the memory sub-system to the set of latches, where the buffer comprises allocated storage space on local memory (e.g., 119) of the memory sub-system controller (e.g., 115). Additionally, for some example embodiments, the set of latches comprises a set of external registers of the memory device configured to interface with and receive data from the memory sub-system controller, and the memory device comprises a set of internal registers that facilitate programming to a set of memory die planes of the memory device. For various example embodiments, the transfer of the first data from the set of external registers to the set of internal registers does not occur until programming of the first data starts. In this way, the set of external registers can receive and store data (e.g., the first data) from the buffer without initiating programming operations. After the first data is transferred to the set of external registers, when programming of the first data to first wordline (WLn) is started, the first data can be transferred from the set of external registers to the set of internal registers to facilitate that programming of the first data to the first wordline on the set of memory die planes, and the first data stored in the set of external registers can be released (e.g., erased or allowed to be released) as the first data is transferred to the set of internal registers, thereby freeing the set of external registers to receive new data (e.g., for the next wordline) from the buffer. The set of external registers can release stored data (e.g., first data) on a page-by-page basis.

After the first data has been transferred to the set of latches, at operation 208 the processing device causes programming of the first data from the set of latches to the first wordline to start (e.g., begin). Operation 208 can comprise sending a set of commands from the processing device (e.g., processor 117) to the memory device (e.g., 130, 140). For some embodiments, if there was a prior wordline (WLn−1) on the set of memory die planes that was being programmed as part of the programming of the target data on the memory device, the processing device would not start the programming of the first data from the set of latches to the first wordline until after the memory device provides a status that indicates that programming of the prior wordline (WLn−1) is successful. If there was no prior wordline (WLn−1), the processing device can cause the programming of the first data from the set of latches to the first wordline to start right after the transfer of the first data has been transferred to the set of latches.

While the first data is being programmed to the first wordline, at operation 210 the processing device causes the second data to be transferred, from a buffer associated with the processing device (e.g., buffer space allocated on the local memory 119 of the memory sub-system controller 115 that includes the processor 117) to the set of latches, for a second wordline (of the plurality of consecutive wordlines of the memory device) on the set of memory die planes, where the second wordline consecutively follows the first wordline. Operation 210 can comprise sending a set of commands from the processing device (e.g., processor 117) to the memory device (e.g., 130, 140). According to various example embodiments, the second data is transferred from the buffer to the set of latches such that the programming of the second data does not automatically start after the transfer of the second data has completed. In doing so, the processing device can delay programming of the second data until after programming of the first data has completed.

As described herein, for some example embodiments, the processing device causes data to be transferred to the set of latches for one page type (e.g., LP, UP, XP, TP, etc.) at a time. For example, where the memory device comprises a NAND-type memory device and the memory cells of the plurality of consecutive wordlines comprise MLCs, the processing device can cause a first portion of the second data to be transfer to the set of latches for pages of a first page type, and cause a second portion of the second data to be transfer to the set of latches for pages of a second page type. The transferring of the first portions of the second data to the set of latches can comprise sending a first set of commands to the memory device that indicates that transfer of data for pages of the first page type (e.g., LP page type) defined by the second wordline is complete (e.g., sending of LP page type for the second wordline is complete). The transferring of the second portions of the second data to the set of latches can comprise sending a second set of commands to the memory device that indicates that transfer of data for pages of the second page type (e.g., UP page type) defined by the second wordline is not complete (e.g., sending of UP page type for the second wordline is not complete). By using the second set of command (to transfer the second data) that indicates that the transfer of data for the second page type (e.g., UP page type) is not complete, the processing device can avoid the memory device automatically starting the programming of the second data (from the set of latches) to the second wordline when the transfer of the second portions of the second data is complete.

As another example, where the memory device comprises a NAND-type memory device and the memory cells of the plurality of consecutive wordlines comprise TLCs, the processing device can cause a first portion of the second data to be transfer to the set of latches for pages of a first page type, cause a second portion of the second data to be transfer to the set of latches for pages of a second page type, and cause a third portion of the second data to be transfer to the set of latches for pages of a third page type. The transferring of the first portions of the second data to the set of latches can comprise sending a first set of commands to the memory device that indicates that transfer of data for pages of the first page type (e.g., LP page type) defined by the second wordline is complete (e.g., sending of LP page type for the second wordline is complete). The transferring of the second portions of the second data to the set of latches can comprise sending a second set of commands to the memory device that indicates that transfer of data for pages of the second page type (e.g., UP page type) defined by the second wordline is complete (e.g., sending of UP page type for the second wordline is complete). The transferring of the third portions of the second data to the set of latches can comprise sending a third set of commands to the memory device that indicates that transfer of data for pages of the third page type (e.g., XP page type) defined by the second wordline is not complete (e.g., sending of XP page type for the second wordline is not complete). By using the third set of command (to transfer the second data) that indicates that the transfer of data for the third page type (e.g., XP page type) is not complete, the processing device can avoid the memory device automatically starting the programming of the second data (from the set of latches) to the second wordline when the transfer of the third portions of the second data is complete. Other examples can be expanded/adapted to cover memory cells with additional page types, such as QLCs, which have LP, UP, XP, and TP page types.

After the second data has been transferred to the set of latches, at operation 212 the processing device checks (e.g., polls) a status of the programming of the first data to the first wordline. Operation 212 can comprise the processing device (e.g., processor 117) checking a status register of the memory device (e.g., 130, 140), or a signal or a response the memory device sends to the processing device. Depending on the example embodiment, the status can be checked (e.g., polled) periodically or in response to another trigger condition. The status of the programming can indicate, for example, that the programming is in progress, successful, or not successful (e.g., failed).

At decision point 214, in response to the processing device determining that the status (checked at operation 212) indicates the programming of the first data to the first wordline is successful, method 200 proceeds to operation 216, where the processing device causes programming of the second data from the set of latches to the second wordline to start. Operation 216 can comprise sending a set of commands from the processing device (e.g., processor 117) to the memory device (e.g., 130, 140). For various example embodiments, where the second data was transferred to the set of latches one page type at a time, and where automatic start of the programming of the second data is prevented (after the transfer of all the page types was completed), the processing device causes programming of the second data (from the set of latches) to start by sending a set of commands to the memory device that indicates that the transfer of data for pages of the last page type to be transferred (e.g., UP, XP or TP page type) defined by the second wordline is now complete.

Alternatively, at decision point 214, in response to the processing device determining that the status (checked at operation 212) indicates the programming of the first data to the first wordline is not successful, method 200 proceeds to operation 218, where the processing device prevents the programming of the second data from the set of latches to the second wordline from starting. In doing so, various example embodiments can save the second data from being lost due to the failure of the programming of the first data. According to various example embodiments, operation 218 causes the second data to remain stored in the set of latches, which can allow the processing device to take subsequent steps responsive to the failure of the programming of the first data. For instance, the processing device can perform error handling to recover the loss of the first data (e.g., using RAIN), and the processing device can retry the programming of the second data to another wordline or another memory die of the memory device.

Table 1 describes an example command sequence for two-plane cache programming, in accordance with some example embodiments. In particular, the example command sequence can represent a sequence of commands sent from the processing device (e.g., processor 117 of the memory sub-system controller 115) to the memory device (e.g., 130, 140) during operations 210, 212, 214, and 216. The example command sequence are performed under the assumption that the memory cells of the memory device comprise TLCs on two memory die planes (with each memory comprising a LP, UP, and XP page type) and that steps 1 through 6 are occurring while data (e.g., first data) is being programmed to a current wordline WL(n).

TABLE 1

| Step | Commands | Description |
|---|---|---|
| 1 | 01h - 80h - ADDR (P0) - DATAIN - | LP data transfer for plane 0 WL(n + 1). |
| | 11h | |
| 2 | 01h - 80h - ADDR (P1) - DATAIN - | LP data transfer for plane 1 WL(n + 1). |
| | 15h | |
| 3 | 02h - 80h - ADDR (P0) - DATAIN - | UP data transfer for plane 0 WL(n + 1). |
| | 11h | |
| 4 | 02h - 80h - ADDR (P1) - DATAIN - | UP data transfer for plane 1 WL(n + 1). |
| | 15h | |
| 5 | 03h - 80h - ADDR (P0) - DATAIN - | XP data transfer for plane 0 WL(n + 1). |
| | 11h | |
| 6 | 03h - 80h - ADDR (P1) - DATAIN - | XP data transfer for plane 1 WL(n + 1). |
| | 11h | |
| 7 | Wait for program passes on WL(n) | FW will wait for program status pass |
| | | on WL(n). |
| 8 | 03h - 85h - ADDR (P1) - 15h | Start WL(n + 1) programming. |

In Table 1, the command sequence of step 1 causes the data to be transferred from the buffer of the memory sub-system to the data latch for a LP page of the next wordline (WLn+1) on memory die plane 0 and indicates (by the 11h command) that transfer of data for LP pages has not finished. The command sequence of step 2 causes the data to be transferred from the buffer of the memory sub-system to the data latch for a LP page of the next wordline (WLn+1) on memory die plane 1 and indicates (by the 15 h command) that transfer of data for LP pages has finished. The command sequence of step 3 causes the data to be transferred from the buffer of the memory sub-system to the data latch for a UP page of the next wordline (WLn+1) on memory die plane 0 and indicates (by the 11h command) that transfer of data for UP pages has not finished. The command sequence of step 4 causes the data to be transferred from the buffer of the memory sub-system to the data latch for a UP page of the next wordline (WLn+1) on memory die plane 1 and indicates (by the 15 h command) that transfer of data for UP pages has finished. The command sequence of step 5 causes the data to be transferred from the buffer of the memory sub-system to the data latch for a XP page of the next wordline (WLn+1) on memory die plane 0 and indicates (by the 11h command) that transfer of data for XP pages has not finished. Lastly, the command sequence of step 6 causes the data to be transferred from the buffer of the memory sub-system to the data latch for a XP page of the next wordline (WLn+1) on memory die plane 1 and indicates (by the 11h command) that transfer of data XP pages has not finished (instead of indicating that it has finished). Afterward, at step 7, the processing device waits for a status of the programming of the current wordline WL(n) to indicate that the programming of the current wordline WL(n) has passed (e.g., was successful). In response to the status indicating that the programming has passed, at step 8, the processing device sends a command sequence (that the 15 h command) to indicate that transfer of data for XP pages has finished.

In comparison to method 200 of FIG. 2, method 300 of FIG. 3 represents the multi-wordline programming of a memory device with data loss prevention in accordance with alternative example embodiments. Referring now to FIG. 3, at operation 302 a processing device (e.g., the processor 117 of the memory sub-system controller 115) receives a request from a host system (e.g., 120) to write target data (e.g., write target data on the memory device 130). For various example embodiments, operation 302 of method 300 is similar with respect to operation 202 of method 200 described with respect to FIG. 2.

In response to the request received at operation 302, at operation 304 the processing device causes at least first data and second data of the target data to be programmed on the memory device. As shown, during operation 304, the processing device performs operations 306 through 320.

At operation 306, the processing device causes the first data to be transferred, from a buffer of a memory sub-system (e.g., buffer space allocated on the local memory 119 of the memory sub-system controller 115) to a set of latches of the memory device, for a first wordline (of the plurality of consecutive wordlines of the memory device) on the set of memory die planes. For various example embodiments, operation 306 of method 300 is similar to operation 206 of method 200 as described with respect to FIG. 2.

After the first data has been transferred to the set of latches, at operation 308 the processing device causes programming of the first data from the set of latches to the first wordline to start (e.g., begin) and causes the buffer of the memory sub-system to release (e.g., erase or enable the erasure of) the first data. Operation 308 can comprise sending a set of commands from the processing device (e.g., processor 117) to the memory device (e.g., 130, 140) to cause the programming of the first data from the set of latches to the first wordline to start. For some embodiments, if there was a prior wordline (WLn−1) on the set of memory die planes that was being programmed as part of the programming of the target data on the memory device, the processing device would not cause the first data to be released from the buffer until after the memory device provides a status that indicates that programming of the prior wordline (WLn−1) is successful.

While the first data is being programmed to the first wordline, at operation 310 the processing device causes the second data to be transferred, from a buffer associated the processing device (e.g., buffer space allocated on the local memory 119 of the memory sub-system controller 115 that includes the processor 117) to the set of latches, for a second wordline (of the plurality of consecutive wordlines of the memory device) on the set of memory die planes, where the second wordline consecutively follows the first wordline. Operation 310 can comprise sending a set of commands from the processing device (e.g., processor 117) to the memory device (e.g., 130, 140). After the second data has been transferred to the set of latches, at operation 312 the processing device causes the programming of the second data to the second wordline (WLn+1) to start and prevents the second data from being released from the buffer. For some example embodiments, the second data is transferred from the buffer to the set of latches such that the programming of the second data automatically starts after the transfer of the second data has completed.

At operation 314, the processing device checks (e.g., polls) a status of the programming of the first data to the first wordline. Operation 312 can comprise the processing device (e.g., processor 117) checking a status register of the memory device (e.g., 130, 140), or a signal or a response the memory device sends to the processing device. Depending on the example embodiment, the status can be checked (e.g., polled) periodically or in response to another trigger condition. The status of the programming can indicate, for example, that the programming is in progress, successful, or not successful (e.g., failed).

At decision point 316, in response to the processing device determining that the status (checked at operation 314) indicates the programming of the first data to the first wordline is successful, method 300 proceeds to operation 318, where the processing device causes the second data to be released from the buffer. Alternatively, at decision point 316, in response to the processing device determining that the status (checked at operation 314) indicates the programming of the first data to the first wordline is not successful, method 300 proceeds to operation 320, where the processing device prevents the second data from being released from the buffer. For instance, the processing device can perform error handling to recover the loss of the first data (e.g., using RAIN), and the processing device can retry the programming of the second data to another wordline or another memory die of the memory device.

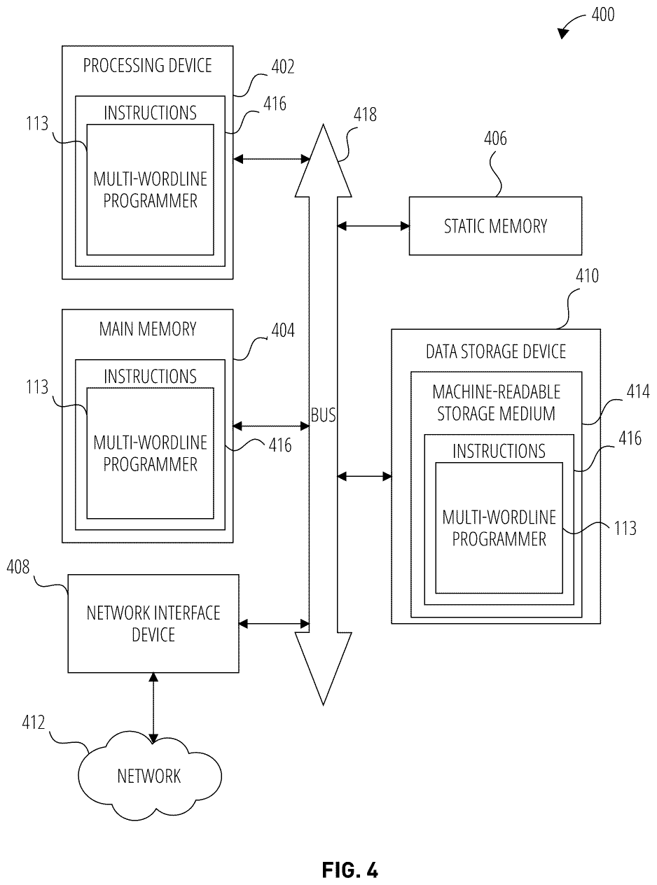

FIG. 4 illustrates an example machine in the form of a computer system 400 within which a set of instructions can be executed for causing the machine to perform any one or more of the methodologies discussed herein. In some example embodiments, the computer system 400 can correspond to a host system (e.g., the host system 120 of FIG. 1) that includes, is coupled to, or utilizes a memory sub-system (e.g., the memory sub-system 110 of FIG. 1) or can be used to perform the operations described herein. In alternative example embodiments, the machine can be connected (e.g., networked) to other machines in a local area network (LAN), an intranet, an extranet, and/or the Internet. The machine can operate in the capacity of a server or a client machine in a client-server network environment, as a peer machine in a peer-to-peer (or distributed) network environment, or as a server or a client machine in a cloud computing infrastructure or environment.

The machine can be a personal computer (PC), a tablet PC, a set-top box (STB), a Personal Digital Assistant (PDA), a cellular telephone, a web appliance, a server, a network router, a switch or bridge, or any machine capable of executing a set of instructions (sequential or otherwise) that specify actions to be taken by that machine. Further, while a single machine is illustrated, the term “machine” shall also be taken to include any collection of machines that individually or jointly execute a set (or multiple sets) of instructions to perform any one or more of the methodologies discussed herein.

The example computer system 400 includes a processing device 402, a main memory 404 (e.g., ROM, flash memory, DRAM such as SDRAM or Rambus DRAM (RDRAM), etc.), a static memory 406 (e.g., flash memory, static random access memory (SRAM), etc.), and a data storage device 410, which communicate with each other via a bus 418.

The processing device 402 represents one or more general-purpose processing devices such as a microprocessor, a central processing unit, or the like. More particularly, the processing device 402 can be a complex instruction set computing (CISC) microprocessor, a reduced instruction set computing (RISC) microprocessor, a very long instruction word (VLIW) microprocessor, a processor implementing other instruction sets, or processors implementing a combination of instruction sets. The processing device 402 can also be one or more special-purpose processing devices such as an application-specific integrated circuit (ASIC), a field programmable gate array (FPGA), a digital signal processor (DSP), a network processor, or the like. The processing device 402 is configured to execute instructions 416 for performing the operations and steps discussed herein. The computer system 400 can further include a network interface device 408 to communicate over a network 412.

The data storage device 410 can include a machine-readable storage medium 414 (also known as a computer-readable medium) on which is stored one or more sets of instructions 416 or software embodying any one or more of the methodologies or functions described herein. The instructions 416 can also reside, completely or at least partially, within the main memory 404 and/or within the processing device 402 during execution thereof by the computer system 400, the main memory 404 and the processing device 402 also constituting machine-readable storage media. The machine-readable storage medium 414, data storage device 410, and/or main memory 404 can correspond to the memory sub-system 110 of FIG. 1.

In one example embodiment, the instructions 416 include instructions to implement functionality corresponding to supporting multi-wordline programming of a memory device with data loss prevention as described herein (e.g., the multi-wordline programmer 113 of FIG. 1). While the machine-readable storage medium 414 is shown in an example embodiment to be a single medium, the term “machine-readable storage medium” should be taken to include a single medium or multiple media that store the one or more sets of instructions. The term “machine-readable storage medium” shall also be taken to include any medium that is capable of storing or encoding a set of instructions for execution by the machine and that cause the machine to perform any one or more of the methodologies of the present disclosure. The term “machine-readable storage medium” shall accordingly be taken to include, but not be limited to, solid-state memories, optical media, and magnetic media.

Described implementations of the subject matter can include one or more features, alone or in combination as illustrated below by way of examples.

Example 1 is a system comprising: a memory device comprising: a set of memory die planes, each memory die plane comprising a plurality of consecutive wordlines of memory cells; and a set of latches for the set of memory die planes; and a processing device, operatively coupled to the memory device, configured to perform operations comprising: receiving a request from a host system to write target data; and in response to the request, causing at least first data and second data of the target data to be programmed on the memory device, the programming of the first data and the second data on the memory device comprising: causing the first data to be transferred from the buffer (e.g., from a buffer allocated on the memory sub-system controller that includes the processing device) to the set of latches for a first wordline of the plurality of consecutive wordlines on the set of memory die planes; after the first data has been transferred to the set of latches, causing programming of the first data from the set of latches to the first wordline to start; while the first data is being programmed to the first wordline, causing the second data to be transferred from the buffer to the set of latches for a second wordline of the plurality of consecutive wordlines on the set of memory die planes, the second wordline consecutively following the first wordline; after the second data has been transferred to the set of latches, checking a status of the programming of the first data to the first wordline; and in response to determining that the status indicates the programming of the first data to the first wordline is successful, causing programming of the second data from the set of latches to the second wordline to start.

In Example 2, the subject matter of Example 1 includes, wherein the programming of the first data and the second data on the memory device comprising: in response to determining that the status indicates the programming of the first data to the first wordline is not successful, preventing the programming of the second data from the set of latches to the second wordline from starting.

In Example 3, the subject matter of Examples 1-2 includes, wherein the set of latches comprises a set of external registers, wherein the memory device comprises a set of internal registers that facilitates programming to the set of memory die planes, and wherein the programming of the first data from the set of latches to the first wordline to start comprises: transferring the first data from the set of external registers to the set of internal registers, the first data being programmed from the set of internal registers to the first wordline; and releasing the first data from the set of external registers.

In Example 4, the subject matter of Example 3 includes, wherein the causing of the transfer of the second data from the buffer to the set of latches while the first data is being programmed to the first wordline comprises: transferring the second data from the buffer to the set of external registers while the first data is being programmed to the first wordline from the set of internal registers.

In Example 5, the subject matter of Examples 1-4 includes, wherein the causing of the transfer of the second data from the buffer to the set of latches while the first data is being programmed to the first wordline comprises: for each page of a first page type defined by the second wordline on each memory die plane of the set of memory die planes, transferring first portions of the second data to the set of latches; and for each page of a second page type defined by the second wordline on each memory die plane of the set of memory die planes, transferring second portions of the second data to the set of latches.

In Example 6, the subject matter of Example 5 includes, wherein the first page type comprises a lower page (LP) type, and wherein the second page type comprises an upper page (UP) type.

In Example 7, the subject matter of Examples 5-6 includes, wherein the memory device comprises a NAND-type memory device, wherein the memory cells of the plurality of consecutive wordlines comprise multi-level cells (MLCs), wherein the transferring of the first portions of the second data to the set of latches comprises sending a first set of commands to the memory device that indicates that transfer of data for pages of the first page type defined by the second wordline is complete, and wherein the transferring of the second portions of the second data to the set of latches comprises sending a second set of commands to the memory device that indicates that transfer of data for pages of the second page type defined by the second wordline is not complete.

In Example 8, the subject matter of Example 7 includes, wherein the causing of the programming of the second data from the set of latches to the second wordline to start comprises: sending a third set of commands to the memory device that indicates that the transfer of data for pages of the second page type defined by the second wordline is complete.

In Example 9, the subject matter of Examples 5-8 includes, wherein the causing of the transfer of the second data from the buffer to the set of latches while the first data is being programmed to the first wordline comprises: for each page of a third page type defined by the second wordline on each memory die plane of the set of memory die planes, transferring third portions of the second data to the set of latches.

In Example 10, the subject matter of Example 9 includes, wherein the first page type comprises a lower page (LP) type, wherein the second page type comprises an upper page (UP) type, and wherein the third page type comprises an extra page (XP) type.

In Example 11, the subject matter of Examples 9-10 includes, wherein the memory cells of the plurality of consecutive wordlines comprise triple-level cells (TLCs), wherein the transferring of the first portions of the second data to the set of latches comprises sending a first set of commands to the memory device that indicates that transfer of data for pages of the first page type defined by the second wordline is complete, wherein the transferring of the second portions of the second data to the set of latches comprises sending a second set of commands to the memory device that indicates that transfer of data for pages of the second page type defined by the second wordline is complete, and wherein the transferring of the third portions of the second data to the set of latches comprises sending a third set of commands to the memory device that indicates that transfer of data for pages of the third page type defined by the second wordline is not complete.

In Example 12, the subject matter of Example 11 includes, wherein the causing of the programming of the second data from the set of latches to the second wordline to start comprises: sending a fourth set of commands to the memory device that indicates that the transfer of data for pages of the third page type defined by the second wordline is complete.

In Example 13, the subject matter of Examples 9-12 includes, wherein the causing of the transfer of the second data from the buffer to the set of latches while the first data is being programmed to the first wordline comprises: for each page of a fourth page type defined by the second wordline on each memory die plane of the set of memory die planes, transferring fourth portions of the second data to the set of latches.

In Example 14, the subject matter of Example 13 includes, wherein the first page type comprises a lower page (LP) type, wherein the second page type comprises an upper page (UP) type, wherein the third page type comprises an extra page (XP) type, and wherein the fourth page type comprises a top page (TP) type.

In Example 15, the subject matter of Examples 13-14 includes, wherein the memory cells of the plurality of consecutive wordlines comprise quad-level cells (QLCs), wherein the transferring of the first portions of the second data to the set of latches comprises sending a first set of commands to the memory device that indicates that transfer of data for pages of the first page type defined by the second wordline is complete, wherein the transferring of the second portions of the second data to the set of latches comprises sending a second set of commands to the memory device that indicates that transfer of data for pages of the second page type defined by the second wordline is complete, wherein the transferring of the third portions of the second data to the set of latches comprises sending a third set of commands to the memory device that indicates that transfer of data for pages of the third page type defined by the second wordline is complete, and wherein the transferring of the fourth portions of the second data to the set of latches comprises sending a fourth set of commands to the memory device that indicates that transfer of data for pages of the fourth page type defined by the second wordline is not complete.

In Example 16, the subject matter of Example 15 includes, wherein the causing of the programming of the second data from the set of latches to the second wordline to start comprises: sending a fifth set of commands to the memory device that indicates that the transfer of data for pages of the fourth page type defined by the second wordline is complete.

Example 17 is a method to implement any of Examples 1-16.

Example 18 is at least one machine-readable medium comprising instructions that, when executed by a processing device, cause the processing device to perform operations to implement any of Examples 1-16.

Example 19 is at least one non-transitory machine-readable storage medium comprising instructions that, when executed by a processing device of a memory sub-system, cause the processing device to perform operations comprising: receiving a request from a host system to write target data; and in response to the request, causing at least first data and second data of the target data to be programmed on a memory device of the memory sub-system, the memory device comprising a set of memory die planes and a set of latches for the set of memory die planes, each memory die plane comprising a plurality of consecutive wordlines of cells, the programming of the first data and the second data on the memory device comprising: causing the first data to be transferred from a buffer of the memory sub-system to the set of latches for a first wordline of the plurality of consecutive wordlines on the set of memory die planes; after the first data has been transferred to the set of latches, causing programming of the first data from the set of latches to the first wordline to start and causing the first data to be released from the buffer; while the first data is being programmed to the first wordline, causing the second data to be transferred from the buffer to the set of latches for a second wordline of the plurality of consecutive wordlines on the set of memory die planes, the second wordline consecutively following the first wordline; and after the second data has been transferred to the set of latches: causing programming of the second data from the set of latches to the second wordline to start without release of the second data from the buffer; checking a status of the programming of the first data to the first wordline; and in response to determining that the status indicates the programming of the first data to the first wordline is successful, causing the second data to be released from the buffer.

In Example 20, the subject matter of Example 19 includes, wherein the programming of the first data and the second data on the memory device comprising: in response to determining that the status indicates the programming of the first data to the first wordline is not successful, preventing the second data from being released from the buffer.

Example 21 is a method to implement any of Examples 19-20.

Example 22 is a system to implement any of Examples 19-20.

Some portions of the preceding detailed descriptions have been presented in terms of algorithms and symbolic representations of operations on data bits within a computer memory. These algorithmic descriptions and representations are the ways used by those skilled in the data processing arts to most effectively convey the substance of their work to others skilled in the art. An algorithm is here, and generally, conceived to be a self-consistent sequence of operations leading to a desired result. The operations are those requiring physical manipulations of physical quantities. Usually, though not necessarily, these quantities take the form of electrical or magnetic signals capable of being stored, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. The present disclosure can refer to the action and processes of a computer system, or similar electronic computing device, that manipulates and transforms data represented as physical (electronic) quantities within the computer system's registers and memories into other data similarly represented as physical quantities within the computer system memories or registers or other such information storage systems.

The present disclosure also relates to an apparatus for performing the operations herein. This apparatus can be specially constructed for the intended purposes, or it can include a general purpose computer selectively activated or reconfigured by a computer program stored in the computer. Such a computer program can be stored in a computer-readable storage medium, such as, but not limited to, any type of disk including floppy disks, optical disks, CD-ROMs, and magnetic-optical disks, ROMs, RAMs, EPROMs, EEPROMs, magnetic or optical cards, or any type of media suitable for storing electronic instructions, each coupled to a computer system bus.

The algorithms and displays presented herein are not inherently related to any particular computer or other apparatus. Various general-purpose systems can be used with programs in accordance with the teachings herein, or it can prove convenient to construct a more specialized apparatus to perform the method. The structure for a variety of these systems will appear as set forth in the description below. In addition, the present disclosure is not described with reference to any particular programming language. It will be appreciated that a variety of programming languages can be used to implement the teachings of the disclosure as described herein.

The present disclosure can be provided as a computer program product, or software, that can include a machine-readable medium (such as a non-transitory machine-readable medium) having stored thereon instructions, which can be used to program a computer system (or other electronic devices) to perform a process according to the present disclosure. A machine-readable medium includes any mechanism for storing information in a form readable by a machine (e.g., a computer). In some example embodiments, a machine-readable (e.g., computer-readable) medium includes a machine (e.g., a computer) readable storage medium such as a ROM, RAM, magnetic disk storage media, optical storage media, flash memory components, and so forth. A machine-readable storage medium can be non-transitory (in other words, not having any transitory signals) in that it does not embody a propagating signal. However, labeling a machine-readable storage medium “non-transitory” should not be construed to mean that the machine-readable storage medium is incapable of movement; the machine-readable storage medium should be considered as being transportable from one physical location to another.

In the foregoing specification, example embodiments of the disclosure have been described with reference to specific example embodiments thereof. It will be evident that various modifications can be made thereto without departing from the broader spirit and scope of example embodiments of the disclosure as set forth in the following claims. The specification and drawings are, accordingly, to be regarded in an illustrative sense rather than a restrictive sense.

1. A system comprising:
a memory device comprising:
a set of memory die planes, each memory die plane comprising a plurality of consecutive wordlines of memory cells; and
a set of latches for the set of memory die planes; and
a processing device, operatively coupled to the memory device, configured to perform operations comprising:
receiving a request from a host system to write target data; and
in response to the request, causing at least first data and second data of the target data to be programmed on the memory device, the programming of the first data and the second data on the memory device comprising:
causing the first data to be transferred from a buffer associated with the processing device to the set of latches for a first wordline of the plurality of consecutive wordlines on the set of memory die planes;
after the first data has been transferred to the set of latches, causing programming of the first data from the set of latches to the first wordline to start;
while the first data is being programmed to the first wordline, causing the second data to be transferred from the buffer to the set of latches for a second wordline of the plurality of consecutive wordlines on the set of memory die planes, the second wordline consecutively following the first wordline;
after the second data has been transferred to the set of latches, checking a status of the programming of the first data to the first wordline; and
in response to determining that the status indicates the programming of the first data to the first wordline is successful, causing programming of the second data from the set of latches to the second wordline to start.

2. The system of claim 1, wherein the programming of the first data and the second data on the memory device comprising:
in response to determining that the status indicates the programming of the first data to the first wordline is not successful, preventing the programming of the second data from the set of latches to the second wordline from starting.

3. The system of claim 1, wherein the set of latches comprises a set of external registers, wherein the memory device comprises a set of internal registers that facilitates programming to the set of memory die planes, and wherein the programming of the first data from the set of latches to the first wordline to start comprises:
transferring the first data from the set of external registers to the set of internal registers, the first data being programmed from the set of internal registers to the first wordline; and
releasing the first data from the set of external registers.

4. The system of claim 3, wherein the causing of the transfer of the second data from the buffer to the set of latches while the first data is being programmed to the first wordline comprises:
transferring the second data from the buffer to the set of external registers while the first data is being programmed to the first wordline from the set of internal registers.

5. The system of claim 1, wherein the causing of the transfer of the second data from the buffer to the set of latches while the first data is being programmed to the first wordline comprises:
for each page of a first page type defined by the second wordline on each memory die plane of the set of memory die planes, transferring first portions of the second data to the set of latches; and
for each page of a second page type defined by the second wordline on each memory die plane of the set of memory die planes, transferring second portions of the second data to the set of latches.

6. The system of claim 5, wherein the first page type comprises a lower page (LP) type, and wherein the second page type comprises an upper page (UP) type.

7. The system of claim 5, wherein the memory device comprises a NAND-type memory device, wherein the memory cells of the plurality of consecutive wordlines comprise multi-level cells (MLCs), wherein the transferring of the first portions of the second data to the set of latches comprises sending a first set of commands to the memory device that indicates that transfer of data for pages of the first page type defined by the second wordline is complete, and wherein the transferring of the second portions of the second data to the set of latches comprises sending a second set of commands to the memory device that indicates that transfer of data for pages of the second page type defined by the second wordline is not complete.

8. The system of claim 7, wherein the causing of the programming of the second data from the set of latches to the second wordline to start comprises:
sending a third set of commands to the memory device that indicates that the transfer of data for pages of the second page type defined by the second wordline is complete.

9. The system of claim 5, wherein the causing of the transfer of the second data from the buffer to the set of latches while the first data is being programmed to the first wordline comprises:
for each page of a third page type defined by the second wordline on each memory die plane of the set of memory die planes, transferring third portions of the second data to the set of latches.

10. The system of claim 9, wherein the first page type comprises a lower page (LP) type, wherein the second page type comprises an upper page (UP) type, and wherein the third page type comprises an extra page (XP) type.

11. The system of claim 9, wherein the memory cells of the plurality of consecutive wordlines comprise triple-level cells (TLCs), wherein the transferring of the first portions of the second data to the set of latches comprises sending a first set of commands to the memory device that indicates that transfer of data for pages of the first page type defined by the second wordline is complete, wherein the transferring of the second portions of the second data to the set of latches comprises sending a second set of commands to the memory device that indicates that transfer of data for pages of the second page type defined by the second wordline is complete, and wherein the transferring of the third portions of the second data to the set of latches comprises sending a third set of commands to the memory device that indicates that transfer of data for pages of the third page type defined by the second wordline is not complete.

12. The system of claim 11, wherein the causing of the programming of the second data from the set of latches to the second wordline to start comprises:
sending a fourth set of commands to the memory device that indicates that the transfer of data for pages of the third page type defined by the second wordline is complete.

13. The system of claim 9, wherein the causing of the transfer of the second data from the buffer to the set of latches while the first data is being programmed to the first wordline comprises:
for each page of a fourth page type defined by the second wordline on each memory die plane of the set of memory die planes, transferring fourth portions of the second data to the set of latches.

14. The system of claim 13, wherein the first page type comprises a lower page (LP) type, wherein the second page type comprises an upper page (UP) type, wherein the third page type comprises an extra page (XP) type, and wherein the fourth page type comprises a top page (TP) type.

15. The system of claim 13, wherein the memory cells of the plurality of consecutive wordlines comprise quad-level cells (QLCs), wherein the transferring of the first portions of the second data to the set of latches comprises sending a first set of commands to the memory device that indicates that transfer of data for pages of the first page type defined by the second wordline is complete, wherein the transferring of the second portions of the second data to the set of latches comprises sending a second set of commands to the memory device that indicates that transfer of data for pages of the second page type defined by the second wordline is complete, wherein the transferring of the third portions of the second data to the set of latches comprises sending a third set of commands to the memory device that indicates that transfer of data for pages of the third page type defined by the second wordline is complete, and wherein the transferring of the fourth portions of the second data to the set of latches comprises sending a fourth set of commands to the memory device that indicates that transfer of data for pages of the fourth page type defined by the second wordline is not complete.

16. The system of claim 15, wherein the causing of the programming of the second data from the set of latches to the second wordline to start comprises:
sending a fifth set of commands to the memory device that indicates that the transfer of data for pages of the fourth page type defined by the second wordline is complete.

17. A method comprising:
receiving a request from a host system to write target data; and
in response to the request, causing at least first data and second data of the target data to be programmed on a memory device of a memory sub-system, the memory device comprising a set of memory die planes and a set of latches for the set of memory die planes, each memory die plane comprising a plurality of consecutive wordlines of cells, the programming of the first data and the second data on the memory device comprising:
causing, by a processing device of the memory sub-system, the first data to be transferred from a buffer associated with the processing device to the set of latches for a first wordline of the plurality of consecutive wordlines on the set of memory die planes;
after the first data has been transferred to the set of latches, causing, by the processing device, programming of the first data from the set of latches to the first wordline to start;
while the first data is being programmed to the first wordline, causing, by the processing device, the second data to be transferred from the buffer to the set of latches for a second wordline of the plurality of consecutive wordlines on the set of memory die planes, the second wordline consecutively following the first wordline;
after the second data has been transferred to the set of latches, periodically checking, by the processing device, a status of the programming of the first data to the first wordline; and
in response to determining that the status indicates the programming of the first data to the first wordline is successful, causing, by the processing device, programming of the second data from the set of latches to the second wordline to start.

18. The method of claim 17, wherein the causing of the transfer of the second data from the buffer to the set of latches while the first data is being programmed to the first wordline comprises:
for each page of a first page type defined by the second wordline on each memory die plane of the set of memory die planes, transferring first portions of the second data to the set of latches; and
for each page of a second page type defined by the second wordline on each memory die plane of the set of memory die planes, transferring second portions of the second data to the set of latches.

19. At least one non-transitory machine-readable storage medium comprising instructions that, when executed by a processing device of a memory sub-system, cause the processing device to perform operations comprising:
receiving a request from a host system to write target data; and
in response to the request, causing at least first data and second data of the target data to be programmed on a memory device of the memory sub-system, the memory device comprising a set of memory die planes and a set of latches for the set of memory die planes, each memory die plane comprising a plurality of consecutive wordlines of cells, the programming of the first data and the second data on the memory device comprising:
causing the first data to be transferred from a buffer of the memory sub-system to the set of latches for a first wordline of the plurality of consecutive wordlines on the set of memory die planes;
after the first data has been transferred to the set of latches, causing programming of the first data from the set of latches to the first wordline to start and causing the first data to be released from the buffer;
while the first data is being programmed to the first wordline, causing the second data to be transferred from the buffer to the set of latches for a second wordline of the plurality of consecutive wordlines on the set of memory die planes, the second wordline consecutively following the first wordline; and
after the second data has been transferred to the set of latches:
causing programming of the second data from the set of latches to the second wordline to start without release of the second data from the buffer;
checking a status of the programming of the first data to the first wordline; and
in response to determining that the status indicates the programming of the first data to the first wordline is successful, causing the second data to be released from the buffer.

20. The system of claim 19, wherein the programming of the first data and the second data on the memory device comprising:
in response to determining that the status indicates the programming of the first data to the first wordline is not successful, preventing the second data from being released from the buffer.
